(19) United States
(12) Patent Application Publication
(10) Pub. No.: US 2009/0011803 A1
(43) Pub. Date: Jan. 8, 2009

(54) Method and Systems for Qualifying Glass Windows Using a Thermal Shock

(76) Inventors: Douglas Weber, Arcadia, CA (US); Stephen P. Zadesky, Portolm Valley, CA (US)

Correspondence Address: TECHNOLOGY & INNOVATION LAW GROUP, PC, ATTN: 101, 19200 STEVENS CREEK BLVD., SUITE 240, CUPERTINO, CA, 95014, US

(21) Appl. No.: 11/942,528

(22) Filed: Nov. 19, 2007

Related U.S. Application Data
(60) Provisional application No. 60/958,356, filed on Jul. 3, 2007.

(51) Int. Cl. H04M 1/03; G01N 25/72; H05K 13/00; B29D 22/00

(52) U.S. Cl. 455/575.1; 374/5; 428/34.4; 29/593

(57) ABSTRACT

Methods and apparatus for testing the actual glass parts that are to be used in electronic devices are disclosed. According to one aspect of the present invention, method for qualifying a glass part includes obtaining the glass part, and applying at least one thermal shock to the glass part. Once the thermal shock is applied, it is determined if the glass part qualifies for use in a device, e.g., a portable electronic device. If it is determined that the glass part qualifies for use in the device, the glass part is identified as qualifying for use in the device.

### CROSS-REFERENCE TO RELATED APPLICATION

This application claims priority from Patent Application No. 60/958,356, Attorney Docket No. 101-P591P, entitled “Method and Systems for Qualifying Glass Windows Using a Thermal Shock,” by Weber, filed on Jul. 3, 2007, which is incorporated herein by reference for all purposes.

### BACKGROUND OF THE INVENTION

1. Field of the Invention

The present invention relates to portable electronic media devices such as digital music players and cellular phones and, more particularly, the thermal testing and qualifying of glass windows associated with displays of the electronic media devices during a production process.

2. Description of the Related Art

During the manufacture of glass windows or, more generally, glass members, the micro cracks and/or other points of weakness may arise. A micro crack may weaken a glass member, and may cause the glass member to break or develop large cracks when the glass member encounters undue stress. Undue stress may be applied to a glass member when the glass member is handled, or is assembled into an enclosure of an electronic device. The undue stress may cause micro cracks to propagate or to otherwise expand. Further, when a glass member is assembled into an electronic device, any existing micro cracks may propagate into large cracks and cause the glass member to break, as for example when the electronic device is dropped.

In an effort to ensure that strong, high quality glass members are assembled into electronic devices, a few glass members selected from a production lot of glass members are subjected to stress tests. Often, the glass members created at the beginning of a production run may be stress tested. Stress tests generally include a bending process that destroys the glass members that are tested. If the tested glass members meet or exceed an imposed stress limit, the entire production log is qualified. It should be appreciated that the glass members which were actually subjected to stress tests were destroyed during the course of the stress tests and, hence are not suitable for being assembled into electronic devices. The glass members which are actually qualified, and, which are considered to be suitable for use in electronic devices, are not actually tested. As a result, weakened glass members, such as those which include micro cracks, parts may ultimately be assembled into electronic devices.

A weakened glass member, when assembled or otherwise incorporated into an electronic device, generally compromises the integrity of the electronic device. By way of example, an electronic device which includes a weakened glass member may be particularly susceptible to breakage.

Therefore, what is needed are a method and an apparatus for reducing the likelihood that weakened glass members are incorporated into electronic devices. That is, what is desired is a system which allows weaknesses in glass members to be discovered prior to the glass members becoming incorporated into electronic products.

### SUMMARY OF THE INVENTION

The present invention pertains to techniques that enable the actual glass windows which are to be assembled into a portable electronic device to be thermally shocked such that weaknesses in the glass windows may be exposed prior to assembly.

The present invention may be implemented in numerous ways, including, but not limited to, as a method, system, device, or apparatus. Example embodiments of the present invention are discussed below.

According to one aspect of the present invention, method for qualifying a glass part includes obtaining the glass part, and applying at least one thermal shock to the glass part. Once the thermal shock is applied, it is determined if the glass part qualifies for use in a device, e.g., a portable electronic device. If it is determined that the glass part qualifies for use in the device, the glass part is identified as qualifying for use in the device. In one embodiment, applying the thermal shock includes heating the glass part to a predetermined temperature, and substantially immediately cooling the glass part for a predetermined period of time.

According to another aspect of the present invention, a method for qualifying a batch of glass parts includes obtaining the batch of glass parts and applying one or more thermal shocks to the batch of glass parts. The method also includes inspecting each glass part included in the batch of glass parts to determine if each glass part qualifies for use in a device. Each glass part that is determined to qualify for use is identified in a set of glass parts included in the batch of glass parts as being suitably strong for use in the device. The set of glass parts that are suitably strong does not include any glass parts that are determined not to qualify for use in the device.

In accordance with still another embodiment of the present invention, an electronic device includes a housing and a thermally shocked glass window. The thermally shocked glass window is assembled with the house, and the thermally shocked glass window has previously been heated to a first temperature, and rapidly cooled at a second temperature. In one embodiment, the first temperature is in a first range between approximately 100 degrees Celsius and approximately 150 degrees Celsius, and the second temperature is in a second range between approximately 0 degrees Celsius and approximately 10 degrees Celsius.

According to yet another aspect of the present invention, a method for fabricating an electronic device includes obtaining a housing and a thermally shocked glass window. The thermally shocked glass window has previously been heated to a first temperature and rapidly cooled at a second temperature. The method also includes assembling the thermally shocked glass window to the housing.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, in which:

FIG. 1A is a diagrammatic representation of a first example of an electronic device that includes a thermally shocked glass window in accordance with an embodiment of the present invention.

FIG. 1B is a diagrammatic representation of a second example of an electronic device that includes a thermally shocked glass window in accordance with an embodiment of the present invention.

FIG. 1C is a diagrammatic representation of a third example of an electronic device that includes a thermally shocked glass window in accordance with an embodiment of the present invention.

FIG. 2 is a process flow diagram which illustrates an overall glass production process in accordance with an embodiment of the present invention.

FIG. 3A is a process flow diagram which illustrates a first method of testing glass windows, e.g., step 213 of FIG. 2, that includes applying a thermal shock to the glass windows in accordance with an embodiment of the present invention.

FIG. 3B is a process flow diagram which illustrates a second method of testing glass windows, e.g., step 213 of FIG. 2, that includes applying a plurality of thermal shocks to the glass windows in accordance with an embodiment of the present invention.

FIG. 4 is a process flow diagram which illustrates a method of qualifying tested glass windows, e.g., step 217 of FIG. 2, in accordance with an embodiment of the present invention.

FIG. 5 is a process flow diagram which illustrates a method of performing a thermal shock process on glass windows in accordance with an embodiment of the present invention.

FIG. 6 is a block diagram representation of an overall process associated with obtaining glass windows that are suitable for assembling into an electronic device in accordance with an embodiment of the present invention.

FIG. 7 is a process flow diagram which illustrates a method of identifying temperatures for use in thermally shocking glass windows in accordance with an embodiment of the present invention.

FIG. 8 is a process flow diagram which illustrates a method of assessing mechanical properties of a thermally shocked glass window, e.g., step 713 of FIG. 7, in accordance with an embodiment of the present invention.

### DETAILED DESCRIPTION OF THE INVENTION

Example embodiments of the present invention are discussed below with reference to the various figures. However, those skilled in the art will readily appreciate that the detailed description given herein with respect to these figures is for explanatory purposes, as the invention extends beyond these embodiments.

The invention pertains to techniques that enable glass members to be tested and qualified prior to assembly into a final product, as for example a portable electronic device. The ability to test and to qualify glass members or windows prior to assembling the glass members into electronic devices reduces the likelihood that a defective glass member, e.g., a glass member which includes a micro crack or other point of weakness, is incorporated into an electronic device. Glass members which fail a testing and qualification process may be prevented from being used in electronic devices, while substantially only those glass members which adequately pass the testing and qualification process may actually be used in electronic devices. As such, the integrity of the electronic devices in which fully qualified glass members are used may be assured.

As will be appreciated by those skilled in the art, glass resists scratching and, therefore, typically provides a more resistant and preferred surface than plastic especially for portable electronic devices that are placed in bags, cases, backpacks, pockets, and the like. The ability to qualify the glass such that glass which includes micro cracks or other points of weakness, such as chips or scratches, is effectively prevented form being incorporated into portable electronic devices enables the strength and the reliability of the portable electronic devices to be enhanced.

In one embodiment, testing glass members may include applying a thermal shock to each glass member that is obtained from a production run. Applying a thermal shock to a glass member may include first heating, then substantially immediately or instantaneously cooling the glass member. By way of example, approximately every glass member included in a production run may be heated to a predetermined temperature in an oven, subsequently removed from the oven once the predetermined temperature is reached, and then substantially immediately placed in a relatively cold fluid such that a thermal shock is effectively created. The application of a thermal shock to a glass window may cause stress on the glass window, and cause micro cracks in the glass window to propagate. Hence, the glass window may be prevented from being assembled into an electronic device. It should be appreciated, however, that in one embodiment, the application of a thermal shock to a glass member may not affect the essential properties of the glass.

Generally, if a glass member contains micro cracks and, hence, relatively weak, the glass member is more susceptible to breakage and developing large cracks when stresses on the glass are caused by, e.g., during, a thermal shocking process. Alternatively, if the glass member is strong, the glass member typically will not break or develop large cracks during a thermal shocking process. As a result, a qualification process may disqualify glass members which are broken or cracked from being suitable for use in an electronic device, and may qualify glass members which are neither broken nor cracked as being suitable for use in electronic devices. As will be appreciated by those skilled in the art, effectively selecting the best and strongest parts for use in an electronic devices may ensure that the parts are likely to be less susceptible to breakage and cracking in a stressed situation, e.g., when the electronic devices are dropped.

A glass member may generally be substantially any glass part that is incorporated into an electronic device. By way of example, a glass member may be a glass window that is arranged to cover or otherwise protect a display screen of an electronic device. Electronic devices which include a display screen may include, but are not limited to including, portable or handheld electronic devices such a digital media players, cellular telephones, smart telephones, cameras, media recorders, media storage devices, global positioning system (GPS) units, personal digital assistants, remote controls, and computing devices. By way of example, electronic devices into which thermally shocked and qualified glass windows are incorporated may include the iPod family of devices and the iPhone family of devices available commercially from Apple Inc. of Cupertino, Calif.

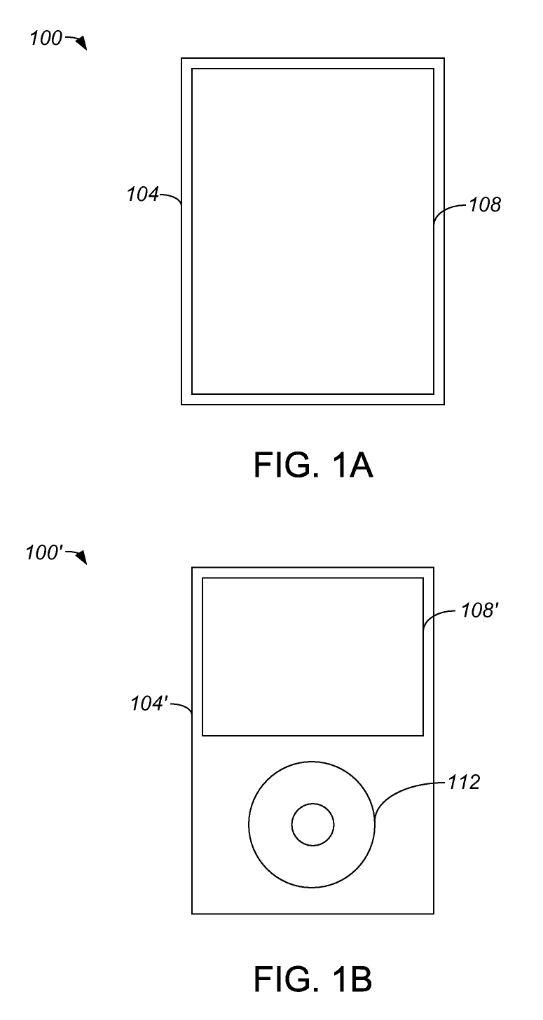

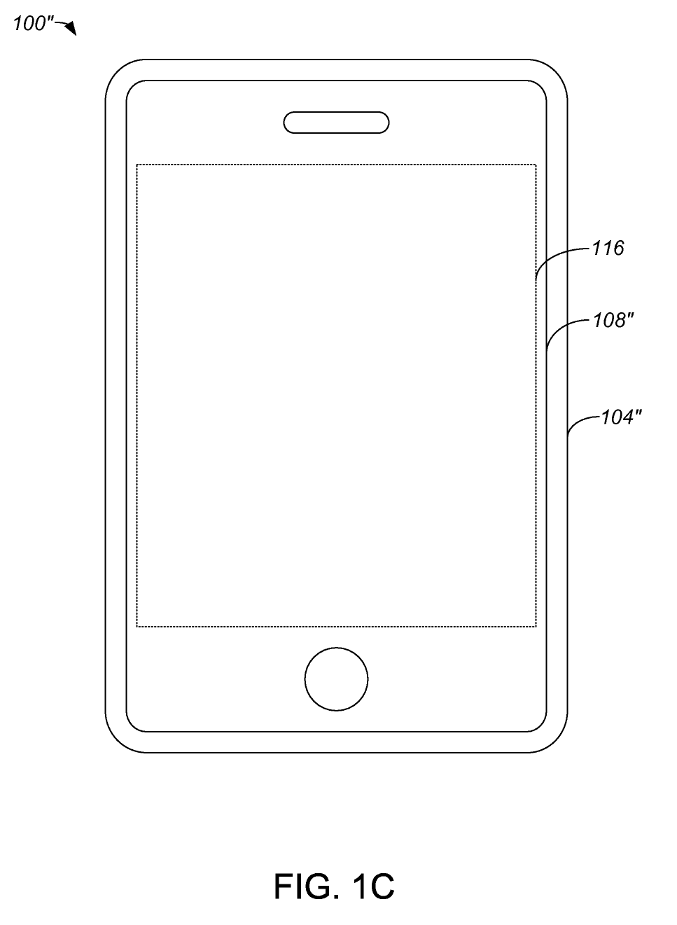

Referring initially to FIGS. 1A-1C, electronic devices into which thermally shocked and qualified glass windows may be incorporated will be described in accordance with an embodiment of the present invention. FIG. 1A is a diagrammatic representation of a first example of an electronic device that includes a thermally shocked glass window in accordance with an embodiment of the present invention. An electronic device 100 includes a body or housing 104 and a glass window 108. Body 104 may house various electrical and/or communications components. Glass window 108 is coupled to, or otherwise assembled with, body 104. Glass window 108 covers substantially an entire front surface of electronic device 100, as a display area of electronic device 100 is a full view or substantially full view display that effectively covers the entire front surface of electronic device 100.

Glass window 108 may generally be arranged or embodied in a variety of ways. By way of example, glass window 108 may be configured as a protective glass piece that is positioned over an underlying display such as a flat panel display (LCD) or touch screen display (LCD and a touch layer). Alternatively, glass window 108 may effectively be integrated with a display, i.e., glass window 108 may be formed as at least up a portion of a display. Additionally, glass window 108 may be substantially integrated with a touch sensing device such as a touch layer associated with a touch screen. In some cases, glass window 108 acts as the outer most layer of the display area.

FIG. 1B is a diagrammatic representation of a second example of an electronic device that includes a thermally shocked glass window in accordance with an embodiment of the present invention. An electronic device 100′ includes a housing 104′ and a glass window 108′. As a front surface of electronic device 100′ also includes a click wheel control 112, glass window 108′ does not cover the entire front surface of electronic device 100′ Electronic device 100′ essentially includes a partial display area that covers a portion of the front surface. Hence, glass window 108′ covers substantially only the display area.

FIG. 1C is a diagrammatic representation of a third example of an electronic device that includes a thermally shocked glass window in accordance with an embodiment of the present invention. An electronic device 100″ includes a housing 104″ and a glass window 108″ that substantially fills the entire top surface of electronic device 100″. In one embodiment, glass window 108″ may be positioned within housing 104″ of electronic device 100″. Housing 104″ may include openings through which a speaker and/or buttons may be accessed. Housing 104″ may also include an opening or recess within which a display or touch screen 116 is positioned. Glass window 108″ overlays at least display or touch screen 116.

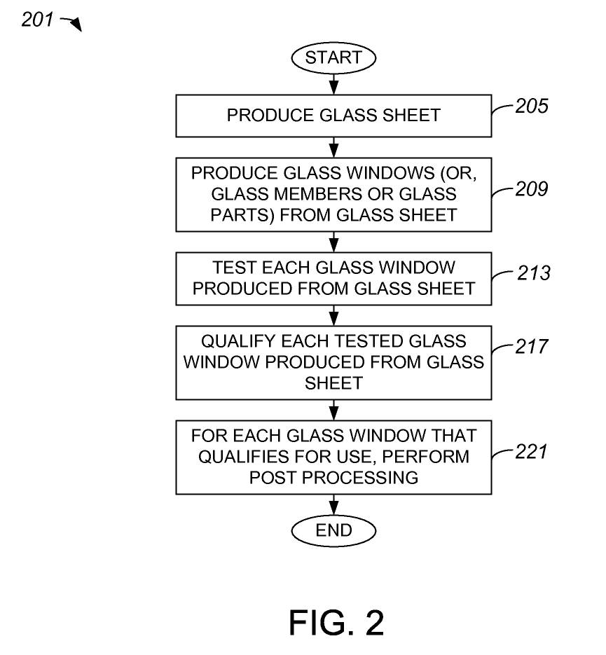

Before a glass window is assembled into an electronic device, the glass window is subjected to a thermal shock that includes heating the glass window and then substantially immediately cooling the glass window. FIG. 2 is a process flow diagram which illustrates an overall glass production process in accordance with an embodiment of the present invention. A process 201 of producing glass windows begins at step 305 in which a glass sheet is produced. Glass sheets may be formed using any suitable glass forming process. Once the glass sheet is produced, glass windows are produced from the glass sheet in step 209. Processes associated with producing glass windows from a glass sheet may include, but are not limited to including, scribing and breaking the glass sheet, cleaning, rough grinding, rough drilling, polishing, creating chamfers, and/or lapping. It should be appreciated that while glass windows are described, substantially any glass member or glass parts may be produced from the glass sheet.

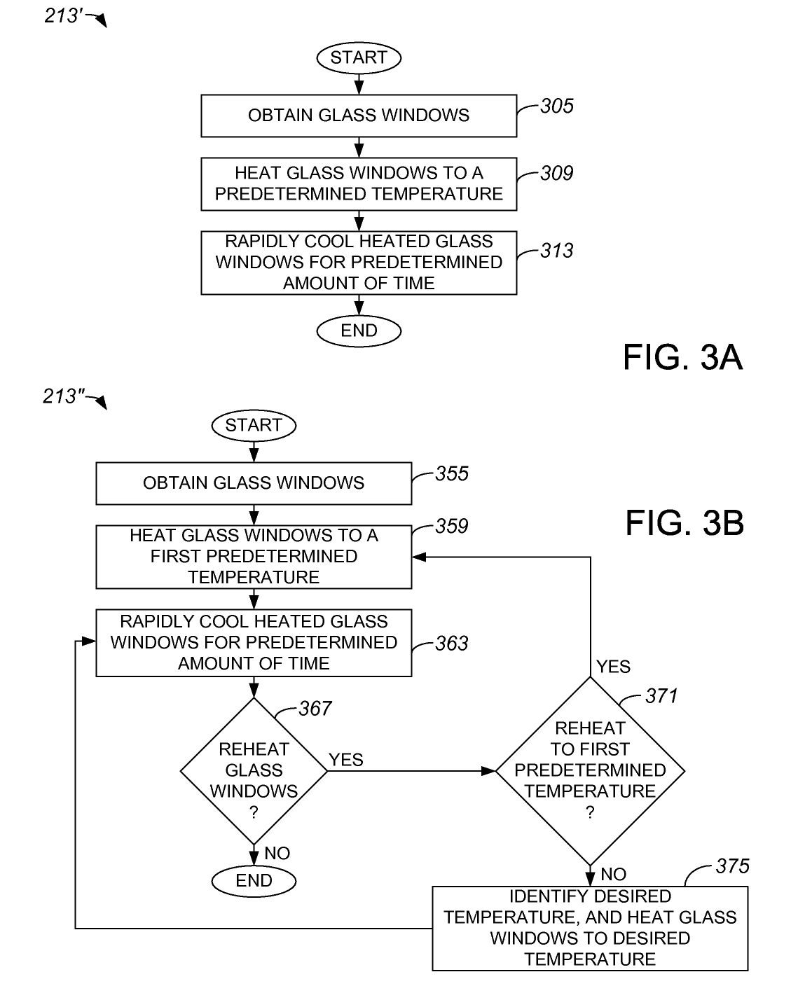

After glass windows are produced from the glass sheet, each glass window that was produced from the glass sheet is tested in step 213. The testing includes thermally testing each glass window. In one embodiment, thermally testing each glass window includes applying a thermal shock to each glass window. Suitable methods of applying thermal shocks to each glass window will be described below with respect to FIGS. 3A and 3B. In general, applying a thermal shock includes elevating the temperature of each glass window to a first temperature, and then substantially immediately cooling each glass window by subjecting each glass window to an environment associated with a second temperature. The first and second temperatures may vary widely. Stress is created on each glass window as a result of substantially instantaneous temperature drops. It should be appreciated that the stress that is typically created on a glass window by an instantaneous temperature drop may generally be calculated, e.g., such that a temperature gradient associated with the temperature drop may be selected to create a desired amount of stress.

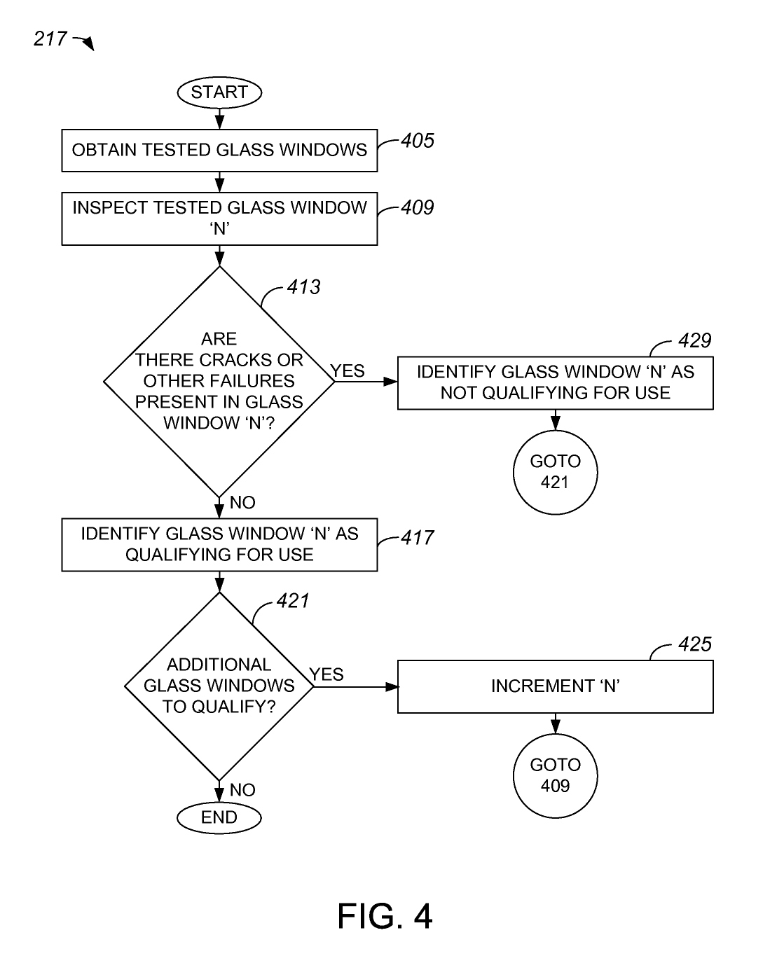

In step 217, each tested glass window is qualified. That is, each tested glass window is studied or processed to ascertain whether it is suitable for use in an electronic device. Generally, qualifying each tested glass window includes visually inspecting each glass window, or subjecting each tested glass window to an automated inspection process arranged to identify imperfections in each tested glass window. In one embodiment, if a tested glass window includes at least one of a crack, a chip, a break, or a scratch, the tested glass window is not qualified for use in an electronic device. Qualifying each tested glass window may also include mechanically assessing each tested glass window, e.g., applying bending forces such as four-point bending forces to each glass window, and evaluating the amount of bending force that each tested glass window may sustain. One qualification process will be discussed below with respect to FIG. 4. Although each tested glass window may undergo a mechanical assessment, it should be appreciated that in some cases, a selected glass window may be mechanically assessed for each batch of tested glass windows. By way of example, if mechanically assessing a tested glass window includes breaking or otherwise weakening the tested glass window, the qualification process may include mechanically assessing a limited number of tested glass windows that are considered to be representative of the overall batch of tested glass windows.

Once relatively weak glass members are effectively filtered out of a production line, process flow proceeds to step 221 in which post processing is performed on each qualified glass window. In other words, glass windows that meet qualification standards, e.g., strength standards, for use in an electronic device are further processed as appropriate. Post processing steps may be widely varied, and may include, but are not limited to including, chemical strengthening, polishing, cleaning, printing, curing, and/or further testing. As will be appreciated by those skilled in the art, by performing post processing steps on substantially only those relatively strong glass members that qualify for use, the time and expense associated with post processing relatively weak glass members may be saved. Upon performing post processing on qualified glass windows, the process of producing glass windows is completed.

As previously mentioned, the methods of testing a glass window, e.g., applying a thermal shock to a glass window, may vary. With reference to FIG. 3A, a first method of testing glass windows, e.g., step 213 of FIG. 2, that includes applying a thermal shock to the glass windows in accordance with an embodiment of the present invention. A process 213′ of testing glass windows begins at step 305 in which glass windows are obtained. Obtaining glass windows may include placing glass windows that result from a production sequence or run into a supporting structure such as a rack.

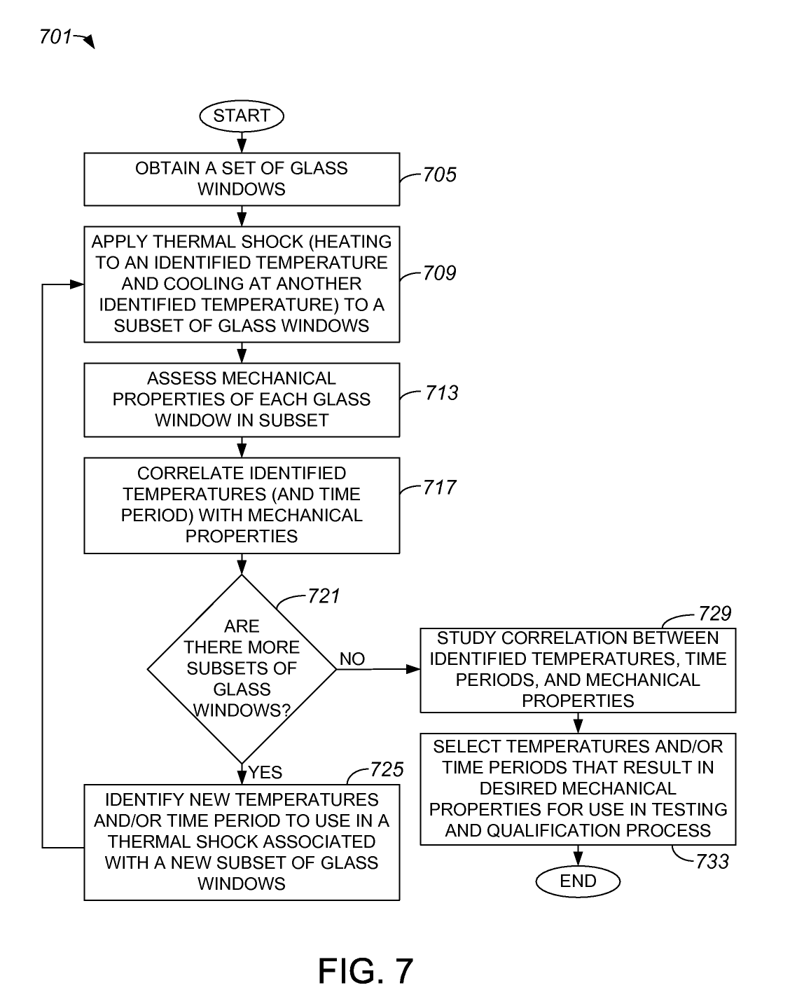

After the glass windows are obtained, the glass windows are heated to a predetermined temperature in step 309. Heating the glass windows may include placing the glass windows in an oven or heating apparatus. The predetermined temperature may correspond to a temperature correlated with desired mechanical properties, as will be discussed below with reference to FIG. 7. That is, the predetermined temperature may be determined using an experimental process. The predetermined temperature may vary widely. For instance, the predetermined temperature may be below approximately 200 degrees Celsius (C), as for example in the range between approximately 100 degrees C. and approximately 150 degrees C. or in the range between approximately 125 degrees C. and approximately 150 degrees C. In addition, the predetermined temperature may be approximately 150 degrees C., approximately 125 degrees C., or approximately 100 degrees C.

Once the glass windows are heated to the predetermined temperature, the heated glass windows are rapidly cooled in step 313 for a predetermined amount of time. Rapidly cooling the heated glass windows may include subjecting the heated glass windows to a medium that has a particular temperature. For example, the heated glass windows may be quenched or otherwise submerged in cold medium such as water. The temperature of the medium may be widely varied. In one embodiment, the temperature of the water is substantially synchronized with the predetermined temperature to which the heated parts were heated in step 309 in order to obtain desired mechanical properties for the glass members. That is, a particular gradient between the temperature to which the glass windows are heated and the cooling temperature may be maintained. Alternatively, the temperature of the cooling medium may be substantially independent of the temperature to which the glass windows are heated. By way of example, the temperature of the cooling medium may be between approximately zero degrees C and ten degrees C.

The predetermined amount of time during which a heated glass window is immersed in a cooling medium, e.g., ice water, may also vary. The amount of time may either be dependent or independent of the predetermined temperature to which the glass windows are heated and the temperature of the cooling medium. In one embodiment, if the predetermined temperature to which the glass windows are heated is in the range between approximately 125 degrees C. and approximately 150 degrees C., and the temperature of the cooling medium is in the range between approximately zero degrees C and approximately ten degrees C, the predetermined time may be in the range between approximately ten seconds and approximately forth seconds, e.g., approximately twenty seconds. After the heated glass windows are rapidly cooled, the process of testing glass windows is completed.

While applying a single thermal shock to each glass window is effective in qualifying glass windows for use in electronic devices, multiple thermal shocks may instead be applied to each glass window. Applying multiple thermal shocks, as for example thermal shocks associated with different heating and cooling temperatures, may provide for a more stringent qualification process. For instance, glass windows intended for electronic devices that are likely to be subjected to higher levels of stress may be subjected to a more stringent qualification process. FIG. 3B is a process flow diagram which illustrates a second method of testing glass windows, e.g., step 213 of FIG. 2, that includes applying more than one thermal shock to the glass windows in accordance with an embodiment of the present invention. A process 213″ of testing glass windows begins at step 355 in which glass windows are obtained. Once glass windows are obtained, the glass windows are heated, e.g., while held in a rack, to a first predetermined temperature in step 359. When the heated glass windows reach a first predetermined temperature, the heated glass windows are relatively rapidly cooled in step 363 for a predetermined amount of time.

After the heated glass windows are cooled, a determination is made in step 367 as to whether the glass windows are to be reheated. In other words, it is determined in step 367 whether another thermal shock, or another heating and cooling process, is to be applied to the glass windows. If it is determined that the glass windows are not to be reheated, the indication is that a desired or otherwise sufficient number of heating and cooling processes have been completed. As such, the process of testing glass windows is completed.

Alternatively, if it is determined in step 367 that the glass windows are to be reheated, the implication is that at least one more thermal shock, or heating and cooling process, is to be applied to the glass windows. As such, process flow moves from step 367 to step 371 in which it is determined if the glass windows are to be reheated to the first predetermined temperature. That is, a temperature to which the glass windows are to be heated is determined. In one embodiment, multiple thermal shocks applied to a group of glass windows may have substantially the same characteristics, e.g., each thermal shock may include heating to the first predetermined temperature. On the other hand, multiple thermal shocks applied to a group of glass windows may have substantially different characteristics, e.g., each thermal shock may be associated with a different predetermined temperature or may be associated with a different temperature gradient. For example, if multiple thermal shocks are applied, a first thermal shock may have a greater thermal gradient than a second thermal shock, and vice versa.

If it is determined in step 371 that the glass windows are to be reheated to the first predetermined temperature, then process flow returns to step 359 in which the glass windows are heated to the first predetermined temperature. Alternatively, if it is determined in step 371 that the glass windows are not to be reheated to the first predetermined temperature, the implication is that the glass windows are to be heated to a different predetermined temperature. Accordingly, in step 375, the temperature to which the glass windows are to be heated is identified, and the glass windows are heated to the identified temperature. Once the temperature is identified, process flow returns to step 363 in which the heated glass windows are relatively rapidly cooled for a predetermined amount of time. It should be appreciated that the predetermined amount of time may vary depending upon the temperature to which the glass windows are heated.

FIG. 4 is a process flow diagram which illustrates a method of qualifying tested glass windows, e.g., step 217 of FIG. 2, in accordance with an embodiment of the present invention. A process 217 of qualifying tested glass windows, or windows which have been subjected to at least one thermal shock, begins at step 405 in which a group of tested glass windows are obtained. Once the tested glass windows are obtained, a single tested glass window may be inspected in step 409. That is, tested glass window ‘N’ is inspected. Inspecting a tested glass window may include, but is not limited to including, visually inspecting each tested glass window and/or utilizing a diagnostic computer program to assess the tested glass window. Inspecting a tested glass window may include ascertaining whether the tested glass window includes a crack, a chip, bubbles, airlines, discoloration, or a scratch. As will be appreciated by those skilled in the art, micro cracks in a glass window may become larger, more noticeable cracks once a thermal shock is applied to the glass window.

After a tested glass window is inspected, it is determined in step 413 whether there are any cracks or other noticeable failures present in the tested glass window. If it is determined that there are no cracks or other noticeable failures in the tested glass window, the glass window is identified in step 417 as being qualified for use. In one embodiment, identifying the glass window as being qualified for use may include identifying the glass window as being suitable for post processing and for assembly into an electronic device. Upon identifying the glass window as qualifying for use, process flow moves to step 421 in which it is determined if there are additional glass windows to qualify.

If the determination in step 421 is that there are no additional glass windows to qualify, the process of qualifying tested glass windows is completed. Alternatively, if it is determined in step 421 that there are additional glass windows to qualify, ‘N’ is incremented in step 425. In other words, the next tested glass window to be inspected is identified. Then, process flow proceeds to step 409 in which the next tested glass window is inspected.

Returning to step 413 and the determination of whether there are cracks or other failures present in the tested glass window, if it is determined that there are cracks or other failures present in the tested glass window, the tested glass window is identified as not qualifying for use in step 429. Once the glass window is identified as not qualifying for use, process flow proceeds to step 421 in which it is determined whether there are additional glass windows to qualify.

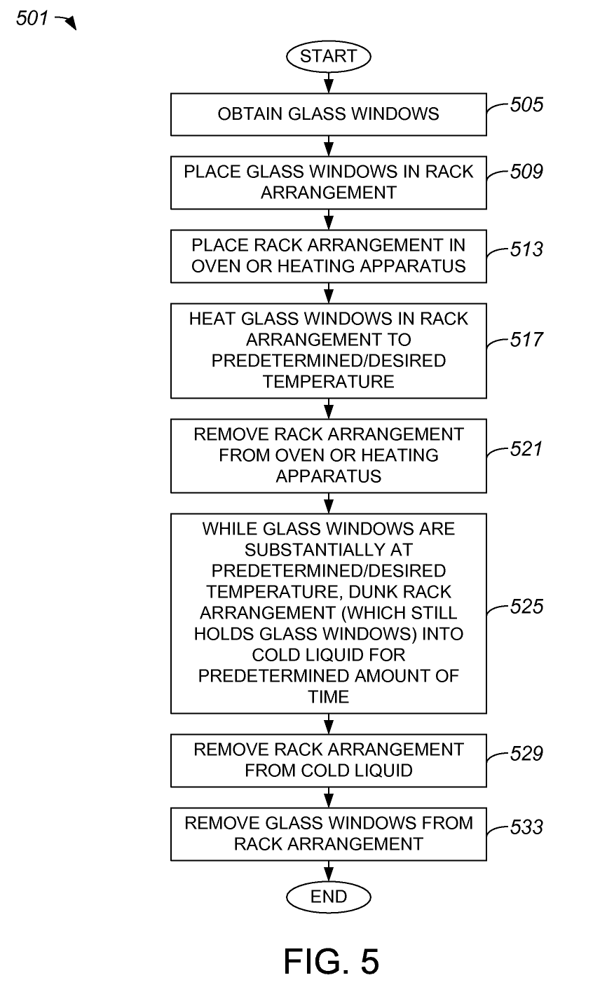

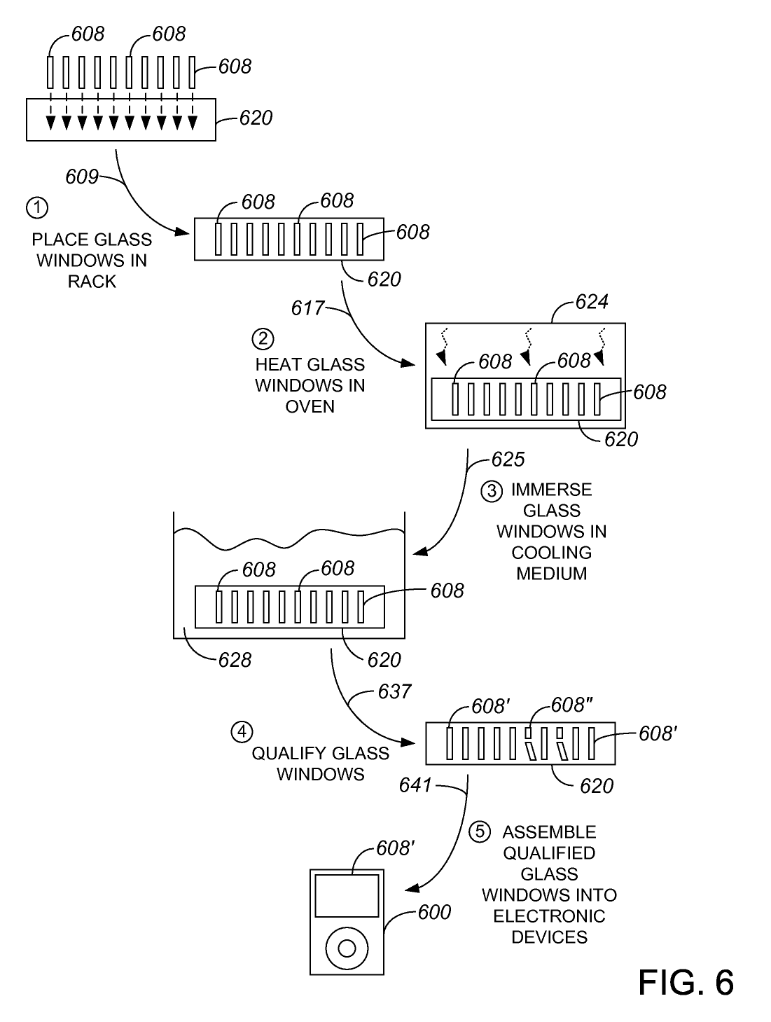

In general, glass windows or parts may be tested in batches. For example, multiple glass members may be subjected to a thermal shock substantially simultaneously. With reference to FIG. 5, a method of implementing a thermal shock process on glass windows will be described in accordance with an embodiment of the present invention. A process 501 of implementing a thermal shock process begins at step 505 in which glass windows are obtained. The glass windows may be obtained form a production run or sequence of glass windows. In step 509, the glass windows are placed in a rack arrangement. The rack arrangement may be a tray that is configured to maintain a separation between each of the glass windows. The rack arrangement may further be arranged to effectively support and retain the glass windows in a desired position within the rack arrangement.

Once the glass windows are placed in the rack arrangement, the rack arrangement is placed in step 513 in an oven or heating apparatus. While the rack arrangement is positioned in the oven or heating apparatus, the glass windows are heated to a predetermined or desired temperature in step 517. As mentioned above, the predetermined or desired temperature may be selected via experimentation. After the glass windows are heated to the predetermined or desired temperature, the rack arrangement is removed from the oven or heating apparatus in step 521.

While the glass windows are substantially still heated to the predetermined or desired temperature, the rack arrangement may be substantially immediately dunked or otherwise plunged in a cold liquid in step 525 for a predetermined amount of time. The temperature of the cold liquid, e.g., iced water, and the length of time may also be selected via experimentation. In one embodiment, the heating temperature, the temperature of the cold liquid, and the length of time for the glass windows to be submerged in the cold liquid may be selected to promote breakage or to relatively severely crack weak glass windows while essentially leaving strong glass windows intact. Typically, the temperature of the cold liquid is monitored and controlled such that the temperature of the cold liquid remains approximately constant while the glass windows are submerged in the cold liquid.

Once the predetermined amount of time elapses, the rack arrangement is removed from the cold liquid in step 529. Then, in step 533, the glass windows are removed from the rack arrangement. It should be appreciated that the weaker glass windows may be damaged or broken, while stronger glass windows may be substantially undamaged and less susceptible to future damage, as for example damage due to the application of undue stress. Removing glass windows from the rack arrangement may include separating cracked or broken glass windows from substantially undamaged glass windows. The process of implementing a thermal shock process is completed once glass windows are removed from the rack arrangement.

Referring next to FIG. 6, the flow associated with a thermal shock process will be discussed. FIG. 6 is a flow diagram of an overall process associated with obtaining glass windows that are suitable for assembling into an electronic device in accordance with an embodiment of the present invention. Initially, glass windows 608 are loaded into a rack 620 in step 609. The loading of glass windows 608 into rack 620 may be accomplished manually, as for example by a person, or automatically, as for example by a pick-and-place mechanical apparatus. Rack 620 may be arranged to maintain a spacing between adjacent glass windows 608. Once glass windows 608 are placed in rack 620, rack 620 may be placed in an oven 624 and heated in step 617. As discussed above, glass windows 608 may be heated to a predetermined temperature that is associated with achieving mechanical properties in glass windows 608 that are appropriate for a given application.

When a desired temperature is achieved relative to glass windows 608, rack 620 is removed from oven 624 and immersed in a cooling medium 628 for a predetermined amount of time in step 625. The cooling medium 628 may be a liquid such as water. After the predetermined amount of time is over, the rack is removed from the cooling medium. Then, glass windows 608 are removed from rack 620 and subjected to a qualification process in step 637. As a result of the thermal shock applied to glass windows 608 in steps 617 and 625, some glass windows 608′ may be intact, while other glass windows 608″ may be damaged or broken. Glass windows 608′ are considered to be relatively strong and, therefore, qualified for use in electronic devices. On the other hand, glass windows 608″ are considered to be relatively weak and, as glass windows 608″ are damaged or broken, are not qualified for use in electronic devices. Qualified glass windows 608′ are assembled into electronic devices 600 in step 641. As will be appreciated by those skilled in the art, qualified glass windows 608′ may be post processed prior to being assembled into electronic devices 600.

In order to determine suitable temperatures for use in thermally shocking glass windows, experiments may be run at different temperatures to ascertain the mechanical properties of the glass windows at each of the different temperatures. Once the mechanical properties are ascertained, suitable temperatures to use in a thermal shock process may be selected. FIG. 7 is a process flow diagram which illustrates a method of identifying temperatures for use in thermally shocking glass windows in accordance with an embodiment of the present invention. A process 701 of determining suitable temperatures to use to thermally shock glass windows begins at step 705 in which a set or a batch of glass windows is obtained. A thermal shock is applied to a subset of the glass windows in step 709. That is, a thermal shock is applied to at least some glass windows. The applied thermal shock may be associated with a first identified heating temperature and a first identified cooling temperature. In addition, the thermal shock may be associated with a first identified time period for which to cool the subset of glass windows.

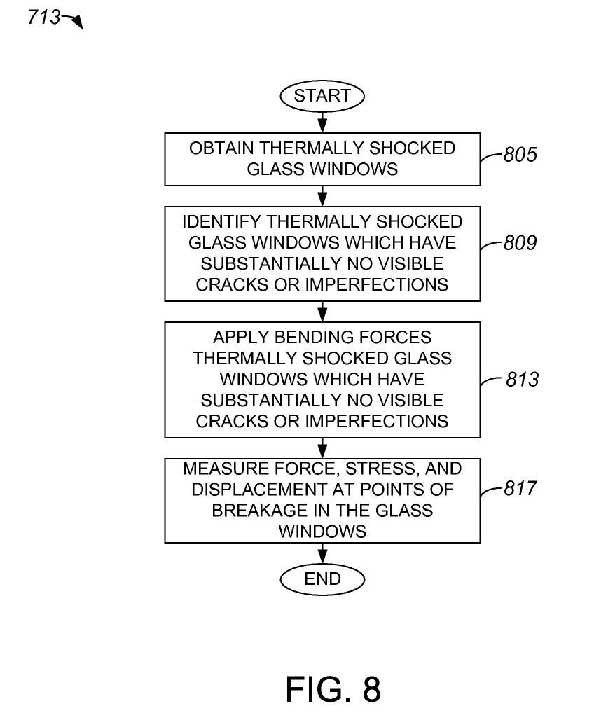

Once the thermal shock is applied, the mechanical properties of each glass window in the subset of glass windows is assessed in step 713. For example, at least some of the glass windows in the subset of glass windows may be subjected to a mechanical test such as a mechanical stress or bending test. One mechanical test that may be applied to glass windows will be described below with reference to FIG. 8. It should be appreciated that assessing mechanical properties of the glass windows in the subset may include comparing the mechanical properties of the glass windows in the subset to the mechanical properties of some glass windows of the set obtained in step 705 which were not thermally shocked.

After the mechanical properties of each glass window in the subset are assessed, the temperatures used in the thermal shock, as well as the cooling time period, are correlated with the mechanical properties in step 717. It is then determined in step 721 whether there are more subsets of glass windows to which a thermal shock is to be applied. If the determination is that there are more subsets of glass windows to which a thermal shock is to be applied, new temperatures and/or a new cooling time period associated with a new thermal shock may be identified in step 725. The new temperatures and/or new cooling time period may be selected based upon obtaining a substantially best match to desired mechanical properties. Once parameters, e.g., temperatures and/or a cooling time period, associated with a new thermal shock are identified, process flow returns to step 709 in which the new thermal shock is applied to the new subset of glass windows.

Returning to step 721, if it is determined that there are no more subsets of glass windows to thermally shock, the correlation between identified temperatures, cooling time periods, and mechanical properties are studied in step 729. Then, in step 733, temperatures and/or cooling time periods that are determined to result in desired mechanical properties are selected for use in a testing and qualification process. It should be appreciated that if multiple thermal shocks are to be applied to glass windows during a testing process, a plurality of temperatures and/or cooling time periods may be selected. Alternatively, if substantially only one thermal shock is associated with a testing process, one heating temperature, one cooling temperature, and one cooling time period may be selected. The process of determining suitable temperatures is completed once temperatures and/or time periods are selected.

With reference to FIG. 8, a method of assessing mechanical properties of a thermally shocked glass window, e.g., step 713 of FIG. 7, will be described in accordance with an embodiment of the present invention. A process 801 of assessing mechanical properties of a thermally shocked glass window begins at step 805 in which thermally shocked glass windows are obtained. After thermally shocked glass windows are obtained, the thermally shocked glass windows may be processed in step 809 to identify any thermally shocked glass windows which are strong, e.g., which have substantially no visible cracks or imperfections.

Once the strong thermally shocked glass windows are identified, bending forces are applied to the strong thermally shocked glass windows in step 813. The application of bending forces may include applying forces substantially axially in an x-direction and/or a y-direction. The bending forces may be applied using approximately four bending points, as for example two points of support and two load points. As will be appreciated by those skilled in the art, the points of support and load points may effectively be areas of support and load areas applied by a mechanical bending device. Typically, applying forces to a glass window substantially axially in either an x-direction or a y-direction may result in a displacement of a portion of the glass window relative to a z-direction.

In step 817, the force, stress, and displacement at a points of breakage in the glass windows are measured. Substantially any suitable method may be used to measure the force, stress, and displacement. The force, stress, and displacement at the points of breakage may be used to determine mechanical properties of the glass windows. The process of assessing mechanical properties is completed once the force, stress, and displacement at the points of breakage are measured or otherwise determined.

Although only a few embodiments of the present invention have been described, it should be understood that the present invention may be embodied in many other specific forms without departing from the spirit or the scope of the present invention. By way of example, although thermal shocks have generally been described as being applied to glass windows, thermal shocks may be applied to substantially any suitable glass part, component, element, or member. Other suitable glass parts may include, but are not limited to including, touchscreen glass panels and/or liquid crystal display (LCD) panels such as those which include two sheets of glass.

The glass which is thermally shocked may be substantially any type of glass. In one embodiment, the glass is a sodium alumino-silicate glass. Further, thermal shocks are not limited to being applied to glass. Rather, thermal shocks may be applied to substantially any member or part which may be subjected to undue forces or stresses when in use as a part of an electronic device.

While thermally shocked and qualified glass windows or parts have been described as being assembled into, or otherwise incorporated into, electronic devices such as digital media players, cellular telephones, and the like. It should be appreciated, however, that qualified glass windows or parts are not limited to being assembled into electronic devices. That is, glass windows or parts which have been subjected to a thermal shock may be assembled into substantially any device, apparatus, or structure.

In addition to applying at least one thermal shock to glass windows during a testing process, a testing process may include a variety of other tests. For example, a testing process may include a mechanical test in which bending forces or stress is applied to glass windows without departing from the spirit or the scope of the present invention. Such a mechanical test may be applied either before or after a thermal shock is applied. If a mechanical test is applied to a glass window after a thermal shock is applied, the mechanical test may be considered to have been successfully passed if the glass window remains substantially intact after the mechanical test is completed.

The size of glass windows to which thermal shocks are applied may vary widely. That is, the length, width, and thickness of a glass window may be varied. In one embodiment, the thickness of a glass window may be in the range between approximately 0.9 millimeters (mm) and approximately 0.95 mm. In another embodiment, the thickness may be between approximately 0.18 mm to approximately 0.3 mm, or between approximately 0.4 mm to approximately 1.2 mm.

Although glass parts have been described as being cooled in a fluid medium such as water, it should be appreciated that the medium used to cool glass parts is not limited to being water. Any suitable cooling fluid may generally be used to cool glass parts. Further, blown or ambient air may also be used to cool glass parts.

In addition to applying thermal shocks, additional shocking means may be used to shock glass parts. For instance, sonic and/or vibrational shocks may be applied sequentially and/or simultaneously with thermal shocks.

The steps associated with the methods of the present invention may vary widely. Steps may be added, removed, altered, combined, and reordered without departing from the spirit of the scope of the present invention. For example, for a qualification process that is associated with multiple thermal shocks, glass windows may effectively be qualified for use between consecutive thermal shocks. In one embodiment, substantially only those glass windows that would qualify for use after a first thermal shock may be subsequently subjected to a second thermal shock. Alternatively, multiple thermal shocks may be performed on a glass window before the glass window is inspected, or otherwise processed, to determine whether the glass window qualifies for use. Therefore, the present examples are to be considered as illustrative and not restrictive, and the invention is not to be limited to the details given herein, but may be modified within the scope of the appended claims.

What is claimed is:

1. A method for qualifying a glass part, the method comprising:
obtaining the glass part;
applying at least one thermal shock to the glass part;
determining if the glass part qualifies for use in a device; and
identifying the glass part as qualifying for use in the device if it is determined that the glass part qualifies for use in the device.

2. The method of claim 1 wherein applying the at least one thermal shock to the glass part includes:
heating the glass part to a first temperature; and
rapidly cooling the heated glass part for a period of time after the glass part is heated to the first temperature.

3. The method of claim 2 wherein rapidly cooling the heated glass part includes:
plunging the glass part into a cold medium; and
maintaining the glass part in the cold medium for the period of time.

4. The method of claim 2 wherein heating the glass part to the first temperature includes placing the glass part in an oven.

5. The method of claim 1 wherein determining if the glass part qualifies for use in the device includes determining if the glass part includes a crack, a chip, a break, or a scratch, wherein if the glass part does not include any of the crack, the chip, the break, or the scratch, it is determined that the glass part qualifies for use in the device.

6. The method of claim 1 wherein determining of the glass part qualifies for use in the device includes applying a bending force to the glass part.

7. A method for qualifying a batch of glass parts, the method comprising:
obtaining the batch of glass parts;
applying at least one thermal shock to the batch of glass parts;
inspecting each glass part included in the batch of glass parts to determine if each glass part qualifies for use in a device; and
identifying a set of glass parts included in the batch of glass parts as being suitably strong for use in the device, wherein the set includes each glass part that qualifies for use in the device and does not include each glass part that does not qualify for use in the device.

8. The method of claim 7 wherein applying the at least one thermal shock to the batch of glass parts includes:
heating the batch of glass parts to a first temperature; and
rapidly cooling the batch of heated glass parts for a period of time after the batch of glass parts is heated to the first temperature.

9. The method of claim 8 further including:
loading the batch of glass parts into a rack, wherein heating the batch of glass parts includes placing the rack in a heating oven, and wherein rapidly cooling the heated batch of glass windows includes plunging the rack into a cold medium and maintaining the rack in the cold medium for the period of time.

10. The method of claim 8 wherein the batch of heated glass parts is cooled at a second temperature, the first temperature being in a first range between approximately 100 degrees Celsius and approximately 150 degrees Celsius, the second temperature being in a second range between approximately 0 degrees Celsius and approximately 10 degrees Celsius.

11. The method of claim 7 wherein applying the at least one thermal shock to the batch of glass parts includes:
applying a first thermal shock to the batch of glass parts, wherein applying the first thermal shock includes heating the batch of glass parts to a first temperature and rapidly cooling the batch of heated glass parts in a medium maintained at a second temperature for a first period of time after the batch of glass parts is heated to the first temperature; and
applying a second thermal shock to at least a subset of the batch of glass parts, wherein applying the second thermal shock includes heating the batch of glass parts to a third temperature and rapidly cooling the batch of heated glass parts in a medium maintained at a fourth temperature for a second period of time after the batch of glass parts is heated to the third temperature.

12. The method of claim 7 wherein the glass parts are glass windows and the device is an electronic device.

13. A system for qualifying a batch of glass parts, the system comprising:
means applying at least one thermal shock to a plurality of glass parts; and
means for assessing each glass part included in the plurality of glass parts to determine whether each glass part of the plurality of glass parts meets qualification standards.

14. The system of claim 13 wherein the means for applying the at least one thermal shock to the plurality of glass parts include:
means for heating the plurality of glass parts to a first temperature; and
means for rapidly cooling the batch of heated glass parts for a period of time after the batch of glass parts is heated to the first temperature.

15. The system of claim 13 wherein the means for applying the at least one thermal shock to the plurality of glass parts include means for cooling the plurality of glass parts at a second temperature, the first temperature being in a first range between approximately 100 degrees Celsius and approximately 150 degrees Celsius, the second temperature being in a second range between approximately 0 degrees Celsius and approximately 10 degrees Celsius.

16. The system of claim 13 wherein the means for applying the at least one thermal shock to the batch of glass parts include:
means for applying a first thermal shock to the batch of glass parts, wherein the means for applying the first thermal shock include means for heating the batch of glass parts to a first temperature and means for rapidly cooling the batch of heated glass parts in a medium maintained at a second temperature for a first period of time after the batch of glass parts is heated to the first temperature; and
means for applying a second thermal shock to at least a subset of the batch of glass parts, wherein the means for applying the second thermal shock include means for heating the batch of glass parts to a third temperature and means for rapidly cooling the batch of heated glass parts in a medium maintained at a fourth temperature for a second period of time after the batch of glass parts is heated to the third temperature.

17. An electronic device comprising:
a housing; and
a thermally shocked glass window, the thermally shocked glass window being assembled with the housing, wherein the thermally shocked glass window has been heated to a first temperature and rapidly cooled at a second temperature.

18. The electronic device of claim 17 wherein the first temperature is in a first range between approximately 100 degrees Celsius and approximately 150 degrees Celsius, and wherein the second temperature is in a second range between approximately 0 degrees Celsius and approximately 10 degrees Celsius.

19. The electronic device of claim 17 wherein the thermally shocked glass window has mechanical properties associated with being heated to the first temperature and rapidly cooled to the second temperature.

20. The electronic device of claim 17 wherein the glass window is formed from a sodium alumino-silicate glass.

21. The electronic device of claim 17 wherein the glass window is integrated with a display or integrated with a touch screen.

22. A method of fabricating an electronic device, the method comprising:
obtaining a housing;
obtaining a thermally shocked glass window, wherein the thermally shocked glass window has been heated to a first temperature and rapidly cooled at a second temperature; and
assembling the thermally shocked glass window to the housing.

23. The method of claim 22 wherein the first temperature is in a first range between approximately 100 degrees Celsius and approximately 150 degrees Celsius, and wherein the second temperature is in a second range between approximately 0 degrees Celsius and approximately 10 degrees Celsius.

24. The method of claim 22 wherein the glass window is integrated with a display or integrated with a touch screen.
